(19) United States
(12) Patent Application Publication
(10) Pub. No.: US 2021/0190636 A1
(43) Pub. Date: Jun. 24, 2021

(54) CONTROL CABINET

(71) Applicant: AVL EMISSION TEST SYSTEMS GMBH, NEUSS (DE)

(72) Inventors: SASCHA WILLICH, KORSCHENBOICH (DE); CHRISTOPHER GARTHE, KAARST (DE); SONJA OPITZ, DUESSELDORF (DE)

(73) Assignee: AVL EMISSION TEST SYSTEMS GMBH, NEUSS (DE)

(21) Appl. No.: 16/756,127

(22) PCT Filed: Sep. 10, 2018
(86) PCT No.: PCT/EP2018/074313

§ 371 Date: Apr. 15, 2020

(30) Foreign Application Priority Data
Oct. 17, 2017 (DE) 10 2017 124 152.3

(51) Int. Cl. G01M 15/10; G01N 1/22

(52) U.S. Cl. CPC G01M 15/102; G01N 2001/2255; G01N 1/2252

(57) ABSTRACT

A control cabinet for an exhaust gas measuring system includes a cabinet body with a component having an inlet and an outlet arranged therein. The outlet is connected via a first connection element to an outlet tube, and the inlet is connected via a second connection element to an inlet tube. The first or second connection element is selectively mounted in a first connection position or in a second connection position so that the outlet tube connecting to the first connection element or the inlet tube connecting to the second connection element is aligned horizontally in the first connection position and vertically in the second connection position. The first connection element or the second connection element are adapted to be mounted in the first connection position and in the second connection position via a 180° rotation in the outlet connection plane.

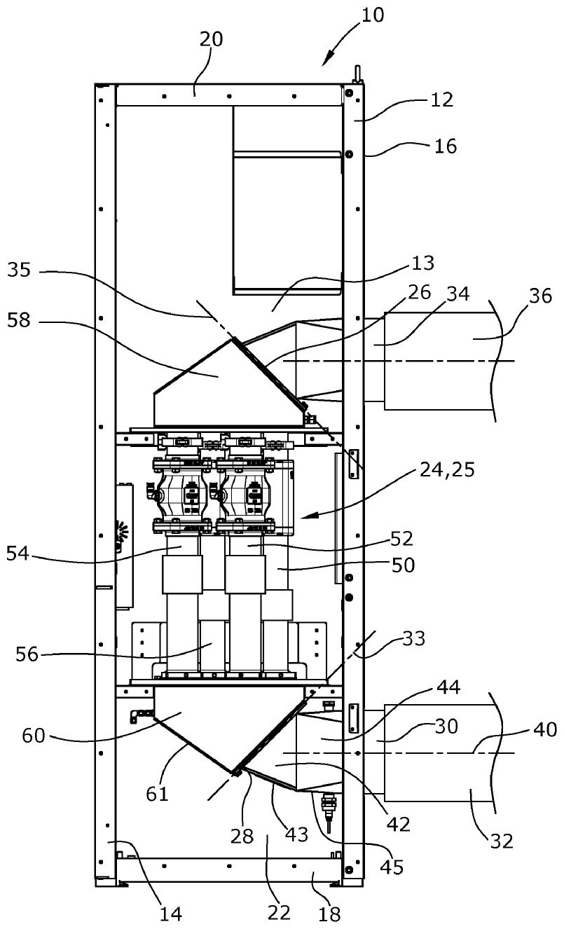

### CROSS REFERENCE TO PRIOR APPLICATIONS

This application is a U.S. National Phase application under 35 U.S.C. § 371 of International Application No. PCT/EP2018/074313, filed on Sep. 10, 2018 and which claims benefit to German Patent Application No. 10 2017 124 152.3, filed on Oct. 17, 2017. The International Application was published in German on Apr. 25, 2019 as WO 2019/076538 A1 under PCT Article 21(2).

### FIELD

The present invention relates to a control cabinet for an exhaust gas measuring system comprising a cabinet body in which a component of the exhaust gas measuring system having an inlet and an outlet is arranged, whereby the outlet is connected via a first connection element to an outlet tube and the inlet is connected via a second connection element to an inlet tube, whereby the first or the second connection element is adapted to be mounted selectively in a first connection position or in a second connection position so that the outlet tube or the inlet tube connecting to the first or the second connection element is aligned horizontally in the first connection position and vertically in the second connection position.

### BACKGROUND

Such exhaust gas measuring systems are used to determine the emission behavior of vehicles, for example, whereby a predefined driving cycle is simulated on a chassis dynamometer and the exhaust gases thereby emitted are analyzed for pollutants contained in the exhaust gas. The amount of carbon dioxide, carbon monoxide, hydrocarbon, and nitrogen oxide are thereby in particular determined. The exhaust gas measuring system generally comprises an exhaust gas dilution system.

The individual components of the exhaust gas measuring system are generally arranged in a plurality of control cabinets. Specific components of the exhaust gas measuring system arranged in the control cabinets are flowed through by the exhaust gas, so that said components comprise an inlet and an outlet. An outlet tube is connected at the outlet and an inlet tube is connected at the inlet to the control cabinet, whereby the position and alignment of the inlet tube and in particular of the outlet tube are specified in advance by the customer even before the control cabinet is set up, so that the control cabinet must be adapted to these specifications.

EP 2 317 833 A1 describes a control cabinet, whereby a component of an exhaust gas measuring system is arranged in the control cabinet. This component comprises an inlet and two outlets, whereby the inlet is arranged in the upper area of the control cabinet and is connected to an inlet tube via a first connection element passing through a ceiling element of the control cabinet. The two outlets are arranged in the lower area of the control cabinet and can be connected via two connection elements to an outlet tube. Various connection elements are required for the first connection position and the second connection position depending on the position and the alignment of the outlet tube, whereby the second connection element is mounted to the first outlet in the first connection position and to the second outlet in the second connection position.

In the first connection position, the second connection element penetrates a side wall of the control cabinet so that a horizontal outlet tube is connected via the second connection element to the first outlet. In the second connection position, the second connection element penetrates a bottom element of the control cabinet so that a vertical outlet tube arranged below the control cabinet is connected via the alternative second connection element to the second outlet.

A disadvantage of the control cabinet described in EP 2 317 833 A1 is that in order to connect the outlet to the outlet tube, whose position and alignment are specified even before the control cabinet is set up, a plurality of outlets with different connection elements are provided and the production and installation effort are therefore increased.

### SUMMARY

An aspect of the present invention is to provide a control cabinet for an exhaust gas measuring system which can be set up independent of the position and the alignment of the outlet tube or the inlet tube, wherein the connection between the outlet and the outlet tube or the connection between the inlet and the inlet tube, respectively, can therefore be established and mounted in a simple and cost-effective manner without additional components being needed.

In an embodiment, the present invention provides a control cabinet for an exhaust gas measuring system which includes a cabinet body, a first connection element, an outlet tube, a second connection element, an inlet tube, and a component of the exhaust gas measuring system arranged in the cabinet body. The component comprises an inlet and an outlet. The outlet is connected via the first connection element to the outlet tube, and the inlet is connected via the second connection element to the inlet tube. The first connection element or the second connection element is configured to be mounted selectively in a first connection position or in a second connection position so that the outlet tube connecting to the first connection element or the inlet tube connecting to the second connection element is aligned horizontally in the first connection position and vertically in the second connection position. The outlet is arranged in an outlet connection plane or the inlet is arranged in an inlet connection plane, each of the outlet connection plane and the inlet connection plane comprising an angle of 45° with respect to a horizontal plane. The first connection element is formed to be angled-tube-like, the angled-tube-like first connection element being adapted to be mounted in the first connection position and in the second connection position via a 180° rotation in the outlet connection plane, or the second connection element is formed to be angled-tube-like, the angled-tube-like second connection element being adapted to be mounted in the first connection position and in the second connection position via a 180° rotation in the inlet connection plane.

### BRIEF DESCRIPTION OF THE DRAWING

The present invention is described in greater detail below on the basis of embodiments and of the drawing in which:

The FIGURE schematically shows a control cabined for an exhaust gas measuring system according to the present invention.

### DETAILED DESCRIPTION

Since the outlet or the inlet is provided in a connection plane, which includes an angle of 45° with respect to a horizontal plane, and the first or the second connection element is formed to be angled-tube-like, wherein the angled-tube-like first or second connection element is adapted to be mounted in the first connection position and in the second connection position via a 180° rotation in the connection plane, the control cabinet can be positioned independent of the position and the alignment of the outlet tube or the inlet tube, whereby a single outlet or inlet is provided which can be connected depending on the position or the alignment of the outlet tube or the inlet tube via the angled-tube-like connection element and by the corresponding installation of the connection element in the first connection position or in the second connection position.

With such an arrangment of the outlet or the inlet and the connection element, a simple and cost-effective connection between the outlet and the outlet tube or between the inlet and the inlet tube is established, whereby the connection element only needs to be rotated by 180° for shifting between the first and the second connection position.

In an embodiment of the present invention, the first and the second connection element can, for example, be adapted to be mounted selectively in a first connection position or in a second connection position, so that the inlet tube connecting to the first connection element and the outlet tube connecting to the second connection element are aligned horizontally in the first connection position and vertically in the second connection position, whereby the outlet and the inlet are each provided in a connection plane, whereby the connection plane includes an angle of 45° with respect to a horizontal plane and the first and the second connection element are angled-tube-like, whereby the angled-tube-like first and second connection elements are adapted to be mounted in the first connection position and in the second connection position via a 180° rotation in the respective connection plane. In case of a specified position and alignment of the inlet tube, the inlet can thus be connected to the inlet tube, and in case of a specified position and alignment of the outlet tube, the outlet can thus be connected to the outlet tube in a simple and cost-effective manner.

In an embodiment of the present invention, the component of the exhaust gas measuring system, in particular of the exhaust gas dilution system, can, for example, comprise a plurality of flow-through tubes entering into a collection inlet and into a collection outlet, whereby the outlet is provided at the collection outlet and the inlet is provided at the collection inlet. Each of the flow-through tubes generally comprises a control valve so that, by operating the control valve, individual flow-through tubes can be shut off or opened for measurement purposes. By providing the collection inlet and the collection outlet, the supply and the discharge of the gas flowing in the flow-through tubes are performed in a cost-effective and installation space-efficient manner via only one single component.

In an embodiment of the present invention, the collection outlet and/or the collection inlet can, for example, be provided with two opposite connection planes, whereby a first connection plane and a second connection plane each include an angle of 45° together with the horizontal plane, and whereby the connection planes are arranged perpendicular to each other. The connection element can thus be mounted in the first and in the second connection position and in the first and in the second connection plane. The connection element can thus be arranged in four different connection positions, thereby increasing the flexibility of the positioning of the control cabinet.

In an embodiment of the present invention, the first connection element and/or the second connection element can, for example, comprise at least one first portion connected to the collection inlet or the collection outlet and at least one second portion connecting to the first portion, whereby a wall of the first portion, a wall of the second portion, and a wall of the collection outlet and/or the collection inlet each include an angle with a longitudinal axis of the connection element, whereby, in the first connection position of the connection element, the angle of the wall of the collection outlet or the collection inlet to the horizontal longitudinal axis is larger than the angle of the wall of the first portion, and the angle of the wall of the first portion to the horizontal longitudinal axis is larger than the angle of the wall of the second portion, so that a curve-like flow deflection occurs. The flowing gas can thus be deflected in the collection inlet and in the first connection element or in the collection outlet and in the second connection element, so that a dead volume is prevented and the flow losses are reduced.

In an embodiment of the present invention, the component of the exhaust gas measuring system can, for example, be rotatable by 180° about a horizontal axis, whereby the outlet faces the ceiling element in a first position and the bottom element in a second position. The position of the inlet and the outlet can thus be adapted to the position of the inlet tube and the outlet tube in a simple and cost-effective manner.

In an embodiment of the present invention, the component of the exhaust gas measuring system can, for example, be a flow control device of a CVS system, whereby a dilution tunnel is connected via the inlet tube to the flow control system. In the CVS system, the exhaust gases emitted by a vehicle and during a predetermined driving cycle are first diluted with air, the diluted exhaust gases are collected in an exhaust gas bag, and the diluted exhaust gases collected in the exhaust gas bag are analyzed by an analysis device for pollutants contained in the exhaust gas. The exhaust gases are diluted with air for measurement purposes in the dilution tunnel, whereby the dilution tunnel is formed by the inlet tube or is connected via the inlet tube to the flow control device.

In an embodiment of the present invention, the component of the exhaust gas measuring system can, for example, be a flow control device of a CVS system, whereby a fan is connected via the outlet tube to the flow rate device. The volume flow flowing through the flow control device is generated by the fan.

A control cabinet for an exhaust gas measuring system is thus provided which can be set up independent of the position and the alignment of the outlet tube, whereby the connection between the outlet and the outlet tube therefor is provided in a simple and cost-effective manner.

The present invention is described in greater detail below under reference to the accompanying drawing.

Control cabinet 10 comprises a cabinet body 12 having a first side wall 14, an opposite second side wall 16, a bottom element 18, a ceiling element 20, and a back wall 22. A door is arranged (the door not being shown in the FIGURE) at the side opposite to back wall 22 via which an engagement with an interior 13 of cabinet body 12 is enabled in an opened position. A component 24 of an exhaust gas measuring system is arranged in interior 13 of cabinet body 12.

Component 24 of the exhaust gas measuring system is a flow control device 25 of a CVS system, whereby in a CVS system, the exhaust gas emitted by a vehicle is introduced into a dilution tunnel during a test cycle and is therein diluted with air. The diluted exhaust gas is then introduced into flow control device 25. In flow control device 25, a volume flow of the diluted exhaust gas being constant and required for the measurement is adjusted before the diluted exhaust gas is extracted by a sampling probe and supplied to one or a plurality of exhaust gas bags. After completion of the driving cycle, the diluted exhaust gas collected in the exhaust gas bag is analyzed for pollutants by a plurality of analysis devices, wherein the amount of carbon dioxide, carbon monoxide, hydrocarbon, and nitrogen oxide is in particular determined.

Flow control device 25 comprises four flow-through tubes 50, 52, 54, 56 which enter into a connection inlet 58 with a first axial end and into a collection outlet 60 with the opposed second axial end. For adjusting the constant volume flow and for adjusting the degree of dilution, each respective flow-through tube 50, 52, 54, 56 comprises one Venturi nozzle operated in a supercritical range and one control valve, respectively.

Collection outlet 60 comprises four openings through which the four flow-through tubes 50, 52, 54, 56 are inserted into collection outlet 60. An outlet 28 of flow control device 25 is also provided at collection outlet 60, whereby outlet 28 is in fluid communication with an outlet tube 32 via a first connection element 30 being connected to outlet 28 in a connection plane 33. A fan (which is not shown in the FIGURE) is connected to outlet tube 32 for generating a flow through the flow control device 25.

According to the present invention, connection plane 33 includes an angle of 45° with respect to the horizontal plane and the first connection element 30 is formed to be angled-tube-like, whereby the first connection element 30 can be mounted in a first and a second connection position.

For shifting the first connection element 30 from the first connection position to the second connection position, the first connection element 30 is rotated in connection plane 33 by 180°.

In the first connection position 30, as shown in the FIGURE, the first connection element 30 is aligned so that the first connection element 30 can be connected with a horizontally aligned connection tube 32. The first connection element 30 thereby penetrates the second side wall 16 so that the first connection element 30 is connected to outlet tube 32 outside cabinet body 12. Outlet tube 32 connecting to the first connection element 30 can otherwise pass vertically. The first connection element 30 is here mounted in the second connection position (which is not shown in the FIGURE), whereby the first connection element 30 penetrates bottom element 18 and is connected to outlet tube 32 below cabinet body 12.

For a flow through collection outlet 60 and the first connection element 30 with little losses and disruptions, the first connection element 30 comprises a first portion 42 connected to outlet 28 and a second portion 44 connecting to the first portion 42, whereby a wall 43 of the first portion 42, a wall 45 of the second portion 44, and a wall 61 of collection outlet 60 each include an angle with a longitudinal axis 40 of the first connection element 30. The angle decreases downstream from wall 61 of collection outlet 60 to wall 43 of the second portion 44 so that a curve-like flow deflection of the gas flowing out of flow control device 25 occurs. In the second connection position of the first connection element 30, the gas flowing out of flow control device 25 flows out of the first connection element 30 parallel to the through-flow of flow control device 25 so that no 90° flow deflection occurs.

Collection inlet 58 is adapted in the same way as collection outlet 60, whereby collection inlet 58 comprises inlet 26. Inlet 26 is in fluid communication with an inlet tube 36 via a second connection element 34 being coupled to inlet 26 in a connection plane 35, whereby the second connection element 34 can be mounted in a first connection position and in a second connection position and can thus be coupled to the vertically or horizontally aligned inlet tube 36. Inlet tube 36 forms a dilution tunnel of the CVS system. Inlet tube 36 alternatively serves as a connection tube between the dilution tunnel and the second connection element 34.

In the embodiment shown in the FIGURE, outlet tube 32 is arranged in the upper area of cabinet body 12, and inlet tube 36 is arranged in the lower area of cabinet body 12, so that flow control device 25 is aligned in the cabinet body 12 with inlet 26 facing ceiling element 20 and outlet 28 is facing bottom element 18. Inlet 26 could alternatively face bottom element 18 and outlet 28 could face ceiling element 20, whereby flow control device 25 is rotated by 180° about a horizontal axis therefor.

A control cabinet for an exhaust gas measuring system is thus provided which can be set up independent of the position and the alignment of the outlet tube, whereby the connection of the outlet to the outlet tube can be established and mounted in a simple and cost-effective manner therefor. A connection to the opposed side wall is also possible by rotating the collection inlet or the collection outlet.

It should be clear that the scope of protection of the present invention is not limited to the described exemplary embodiment of the control cabinet. The connection element or the collection outlet can, for example, be configured in a different manner. Another component of the exhaust gas measuring system, for example, a heat exchanger, could also, for example, be arranged in the control cabinet.

The present invention is not limited to embodiments described herein; reference should be had to the appended claims.

What is claimed is:

1-8. (canceled)

9: A control cabinet for an exhaust gas measuring system, the control cabinet comprising:
a cabinet body;
a first connection element;
an outlet tube;
a second connection element;
an inlet tube; and
a component of the exhaust gas measuring system arranged in the cabinet body, the component comprising an inlet and an outlet, the outlet being connected via the first connection element to the outlet tube, and the inlet being connected via the second connection element to the inlet tube,
wherein,
the first connection element or the second connection element is configured to be mounted selectively in a first connection position or in a second connection position so that the outlet tube connecting to the first connection element or the inlet tube connecting to the second connection element is aligned horizontally in the first connection position and vertically in the second connection position,
the outlet is arranged in an outlet connection plane or the inlet is arranged in an inlet connection plane, each of the outlet connection plane and the inlet connection plane comprising an angle of 45° with respect to a horizontal plane, and
the first connection element is formed to be angled-tube-like, the angled-tube-like first connection element being adapted to be mounted in the first connection position and in the second connection position via a 180° rotation in the outlet connection plane, or
the second connection element is formed to be angled-tube-like, the angled-tube-like second connection element being adapted to be mounted in the first connection position and in the second connection position via a 180° rotation in the inlet connection plane.

10: The control cabinet as recited in claim 9, further comprising:
a collection inlet; and
a collection outlet,
wherein,
the component of the exhaust gas measuring system further comprises a plurality of flow-through tubes which enter into the collection inlet and into the collection outlet,
the outlet is arranged at the collection outlet, and
the inlet is arranged at the collection inlet.

11: The control cabinet as recited in claim 10, wherein,
at least one of the collection outlet and the collection inlet is provided with a first connection plane and a second connection plane which are arranged opposite to each other,
the first connection plane and the second connection plane each comprise an angle of 45° with respect to the horizontal plane, and
the first connection plane and the second connection plane are arranged perpendicular to each other.

12: The control cabinet as recited in claim 10, wherein,
at least one of the first connection element and the second connection element comprise at least one first portion which is connected to the collection inlet or to the collection outlet and at least one second portion which connects to the first portion,
wherein,
a wall of the at least one first portion, a wall of the at least one second portion, and a wall of at least one of the collection outlet and the collection inlet each comprise an angle to a longitudinal horizontal axis of the connection element, and
in the first connection position of the connection element, the angle of the wall of the collection outlet or of the collection inlet to the horizontal longitudinal axis is larger than the angle of the wall of the first portion, and the angle of the wall of the first portion to the horizontal longitudinal axis is larger than the angle of the wall of the second portion, so as to provide a curve-like flow deflection.

13: The control cabinet as recited in claim 9, further comprising:
a ceiling element; and
a bottom element,
wherein,
the component of the exhaust gas measuring device is rotatable by 180° about a horizontal axis so that the outlet faces the ceiling element in a first position and the bottom element in a second position.

14: The control cabinet as recited in claim 9, further comprising:
a dilution tunnel,
wherein,
the component of the exhaust gas measuring system is a flow control device of a CVS system, and
the dilution tunnel is connected via the inlet tube to the flow control system.

15: The control cabinet as recited in claim 9, further comprising:
a fan,
wherein,
the component of the exhaust gas measuring system is a flow control device of a CVS system, and
the fan is connected via the outlet tube to the flow control device.

16: A control cabinet for an exhaust gas measuring system, the control cabinet comprising:
a cabinet body;
a first connection element;
an outlet tube;
a second connection element;
an inlet tube; and
a component of the exhaust gas measuring system arranged in the cabinet body, the component comprising an inlet and an outlet, the outlet being connected via the first connection element to the outlet tube, and the inlet being connected via the second connection element to the inlet tube,
wherein,
the first connection element and the second connection element are adapted to be mounted selectively in the first connection position or in the second connection position so that the inlet tube connecting to the first connection element and the outlet tube connecting to the second connection element are aligned horizontally in the first connection position and vertically in the second connection position,
the outlet is arranged in an outlet connection plane and the inlet is arranged in an inlet connection plane, each of the outlet connection plane and the inlet connection plane comprising an angle of 45° with respect to a horizontal plane,
the first connection element is formed to be angled-tube-like, the angled-tube-like first connection element being adapted to be mounted in the first connection position and in the second connection position via a 180° rotation in the outlet connection plane, and
the second connection element is formed to be angled-tube-like, the angled-tube-like second connection element being adapted to be mounted in the first connection position and in the second connection position via a 180° rotation in the inlet connection plane.

17: The control cabinet as recited in claim 16, further comprising:
a collection inlet; and
a collection outlet,
wherein,
the component of the exhaust gas measuring system further comprises a plurality of flow-through tubes which enter into the collection inlet and into the collection outlet,
the outlet is arranged at the collection outlet, and
the inlet is arranged at the collection inlet.

18: The control cabinet as recited in claim 17, wherein,
at least one of the collection outlet and the collection inlet is provided with a first connection plane and a second connection plane which are arranged opposite to each other,
the first connection plane and the second connection plane each comprise an angle of 45° with respect to the horizontal plane, and
the first connection plane and the second connection plane are arranged perpendicular to each other.

19: The control cabinet as recited in claim 17, wherein,
at least one of the first connection element and the second connection element comprise at least one first portion which is connected to the collection inlet or to the collection outlet and at least one second portion which connects to the first portion,
wherein,
a wall of the at least one first portion, a wall of the at least one second portion, and a wall of at least one of the collection outlet and the collection inlet each comprise an angle to a longitudinal horizontal axis of the connection element, and
in the first connection position of the connection element, the angle of the wall of the collection outlet or of the collection inlet to the horizontal longitudinal axis is larger than the angle of the wall of the first portion, and the angle of the wall of the first portion to the horizontal longitudinal axis is larger than the angle of the wall of the second portion, so as to provide a curve-like flow deflection.

20: The control cabinet as recited in claim 16, further comprising:
a ceiling element; and
a bottom element,
wherein,
the component of the exhaust gas measuring device is rotatable by 180° about a horizontal axis so that the outlet faces the ceiling element in a first position and the bottom element in a second position.

21: The control cabinet as recited in claim 16, further comprising:
a dilution tunnel,
wherein,
the component of the exhaust gas measuring system is a flow control device of a CVS system, and
the dilution tunnel is connected via the inlet tube to the flow control system.

22: The control cabinet as recited in claim 16, further comprising:
a fan,
wherein,
the component of the exhaust gas measuring system is a flow control device of a CVS system, and
the fan is connected via the outlet tube to the flow control device.
